(19) United States
(12) Patent Application Publication
(10) Pub. No.: US 2007/0269930 A1
(43) Pub. Date: Nov. 22, 2007

(54) Methodology to control underfill fillet size, flow-out and bleed in flip chips (FC), chip scale packages (CSP) and ball grid arrays (BGA)

(75) Inventors: Vikas Gupta, Dallas, TX (US); Charles Anthony Odegard, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/437,310

(22) Filed: May 19, 2006

(51) Int. Cl. H01L 21/00

(52) U.S. Cl. 438/108

(57) ABSTRACT

In a method and system for underfilling a gap (140) disposed between a substrate (120) and a die (110), a selective surface (152) of the substrate (120) is treated by a plasma source. A matching surface (154) of the die (110) may be treated by the plasma source. The treating results in a roughening of the selective surface (152) and the matching surface (154). The roughening improves welting of an underfill (150) on the selective surface (152) and the matching surface (154) compared to a non-treated surface. The underfill (150) is dispensed to substantially fill the gap (140) disposed between the selective surface (152) and the matching surface (154) of the die 110. The underfill (150) is substantially contained within the gap (140) by the wetting, which reduces the backflow and the bleed of the underfill (150).

### BACKGROUND

The present invention is related in general to the field of electronic systems and semiconductor devices and more specifically to the field of semiconductor device assembly having an underfilling material disposed between the semiconductor device and a substrate.

When a semiconductor device such as an integrated circuit (IC) chip is assembled on an insulating substrate with conducting lines, e.g., a printed circuit board, by solder bump connections, the chip is spaced apart from the substrate by the bumps, thereby forming a gap between the chip and substrate. The IC chip is typically a semiconductor such as silicon, silicon germanium, or gallium arsenide, the substrate is usually made of ceramic or polymer-based materials such as FR-4. Consequently, it is well known that there is a significant difference between the coefficients of thermal expansion (CTE) of the chip and the substrate. As a consequence of this CTE difference, thermomechanical stresses are created at the solder interconnections, especially in the regions of the joints, when the assembly is subjected to temperature cycling during device usage or reliability testing. These stresses tend to fatigue the joints and the bumps, resulting in cracks and eventual failure of the assembly.

In order to distribute the mechanical stress and to strengthen the solder joints without affecting the electrical connection, the gap between the IC chip and the substrate is customarily filled with a polymeric material, which encapsulates the bumps and fills the gap. For example, in the well-known “C-4” process developed by International Business Machines Corporation, polymeric material is used to fill the gap between the IC chip and the ceramic substrate.

The polymeric material is typically applied after the solder bumps have undergone the reflow process and formed the metallic joints for electrical contact between the IC chip and the substrate. A viscous polymeric precursor, also referred to as an “underfill”, is dispensed onto the substrate adjacent to the IC chip and is pulled into the gap by capillary forces. The underfill is typically composed of a resin (or epoxy) and filler particles. The precursor is then heated, polymerized and “cured” to form the encapsulant.

The following U.S. Patents describe various aspects of the tools and methods for performing an underfilling operation, all of which are incorporated herein by reference: 1) U.S. Pat. No. 6,977,429 entitled ‘Manufacturing System And Apparatus For Balanced Product Flow With Application To Low-Stress Underfilling Of Flip-Chip Electronic Devices’, 2) U.S. Pat. No. 6,869,831 entitled ‘Adhesion By Plasma Conditioning Of Semiconductor Chip Surfaces’, 3) U.S. Pat. No. 6,855,578 entitled ‘Vibration-Assisted Method For Underfilling Flip-Chip Electronic Devices’, and 4) U.S. Pat. No. 6,245,583 entitled ‘Low Stress Method And Apparatus Of Underfilling Flip-Chip Electronic Devices’.

However, traditional tools and methods for underfilling may be inadequate to ensure a void free assembly, and may result in producing over encapsulated and/or under encapsulated fillets resulting in a higher stress concentration. In addition, the traditional tools and methods for underfilling may be inadequate to handle backflow and bleed of the underfill. A flow of the underfill away from the die/substrate gap may be described as a backflow. A bleed of the underfill occurs when the resin separates from the filler particles.

Both backflow and bleed of the underfill may be undesirable. The backflow of the underfill may cover other substrate components such as chip capacitors. The backflow may also result in a reduced amount of the underfill that may be insufficient to completely fill the gap, thereby causing voids, and/or resulting in smaller underfill fillet. Bleed may result in localized material property differentials that may be undesirable for package reliability.

### SUMMARY

Applicants recognize an existing need for an improved method and system for performing an underfilling operation to fabricate semiconductor devices; and the need for an improved dispensing of the underfill to minimize bleed and backflow, absent the disadvantages found in the prior techniques discussed above.

The foregoing need is addressed by the teachings of the present disclosure, which relates to a system and method for performing an underfilling operation while fabricating semiconductor devices. According to one embodiment, in a method and system for underfilling a gap disposed between a substrate and a die, a selective surface of the substrate is treated by a plasma source. A matching surface of the die may be treated by the plasma source. The treating results in a roughening of the selective surface and the matching surface. The roughening improves wetting of an underfill on the selective surface and the matching surface compared to a non-treated surface. The underfill is dispensed to substantially fill the gap disposed between the selective surface and the matching surface of the die. The underfill is substantially contained within the gap by the wetting, which reduces the backflow and the bleed of the underfill.

In one aspect of the disclosure, a method for underfilling a gap disposed between a substrate and a die includes applying an underfill flow inhibitor layer to selectively cover a surface area of the substrate except for a selective portion of the surface area. An underfill is dispensed to substantially fill the gap disposed between the selective portion and a matching surface of the die. The underfill is substantially contained within the selective portion in response to an absence of the underfill flow inhibitor layer, thereby reducing the backflow and the bleed.

Several advantages are achieved by the method and system according to the illustrative embodiments presented herein. The embodiments advantageously provide for efficient dispensing of the underfill with a substantially reduced backflow and bleed. The plasma treatment of the surfaces in contact with the underfill advantageously roughens, cleans and activates the surfaces to improve the wetting of the underfill in the treated areas. Wastage due to rework and scrap associated with the underfill backflow and bleed is reduced. This advantageously enables semiconductor manufacturing facilities to improve production rates, quality and reliability.

### BRIEF DESCRIPTION OF THE DRAWINGS

FIG. 1A illustrates a simplified and schematic cross section of a semiconductor device assembly having plasma treated components, according to an embodiment;

FIG. 1B illustrates a top view of a semiconductor device assembly described with reference to FIG. 1A, according to an embodiment;

FIG. 1C illustrates a schematic cross section of a semiconductor device assembly described with reference to FIG. 1A to indicate dispensing of an underfill for filling a gap, according to an embodiment;

FIG. 2A illustrates a simplified and schematic cross section of a semiconductor device assembly having a flow inhibitor layer applied to a selective surface of a substrate, according to an embodiment;

FIG. 2B illustrates a top view of a semiconductor device assembly described with reference to FIG. 2A, according to an embodiment;

FIG. 3A is a flow chart illustrating a method for underfilling a gap disposed between a substrate and a die included in a semiconductor device assembly using a mask, according to an embodiment;

FIG. 3B is a flow chart illustrating a method for plasma treating a selective surface described with reference to FIG. 3A, according to an embodiment; and

FIG. 4 is a flow chart illustrating a method for underfilling a gap disposed between a substrate and a die included in a semiconductor device assembly using a flow inhibitor, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements. Similarly, the functionality of various mechanical elements, members, and/or components for forming modules, sub-assemblies and assemblies assembled in accordance with a structure for an apparatus may be implemented using various materials and coupling techniques, depending on the application requirements.

Traditional tools and methods for underfilling may be inadequate to ensure a void free assembly, and may result in producing over encapsulated and/or under encapsulated fillets resulting in a higher stress concentration. In addition, the traditional tools and methods for underfilling may be inadequate to handle backflow and bleed of the underfill, which may be undesirable. The backflow of the underfill may cover other substrate components such as chip capacitors. The backflow may also result in a reduced underfill being unable to completely fill the gap, thereby causing voids, and/or resulting in smaller underfill fillet. Bleed may result in localized material property differentials that may be undesirable for package reliability. This problem may be addressed by an improved system and method for performing an underfilling operation to fabricate semiconductor devices. According to an embodiment, in an improved system and method for underfilling a gap disposed between a substrate and a die, a selective surface of the substrate is treated by a plasma source. A matching surface of the die may be treated by the plasma source. The treating results in a roughening of the selective surface and the matching surface. The roughening improves wetting of an underfill on the selective surface and the matching surface compared to a non-treated surface. The underfill is dispensed to substantially fill the gap disposed between the selective surface and the matching surface of the die. The underfill is substantially contained within the gap by the wetting, which reduces the backflow and the bleed of the underfill.

The following terminology may be useful in understanding the present disclosure. It is to be understood that the terminology described herein is for the purpose of description and should not be regarded as limiting.

Ball grid array (BGA)—A type of chip package type that enables direct mounting of the chip to a substrate or printed circuit board via solder balls or bumps. The solder balls or bumps are arranged in a grid-style array and found on the underside of the chip to make the electrical connection to the outside.

Flip Chip (FC)—A technique to surface mount a chip or die on to a substrate (or a board) by flipping and directly connecting the chip or die to the substrate without using traditional wire bonding technique. The direct connection is typically via solder balls or conductive bumps. The gap between the chip and the substrate is underfilled with a polymeric material. A FC package configuration includes at least one semiconductor chip or die mounted in an active surface-down manner over a substrate (or another semiconductor chip) electrically and mechanically coupled to the same by means of the conductive bumps.

Chip scale package (CSP)—A chip package in which the total package size is no more than 20% greater than the size of the die within.

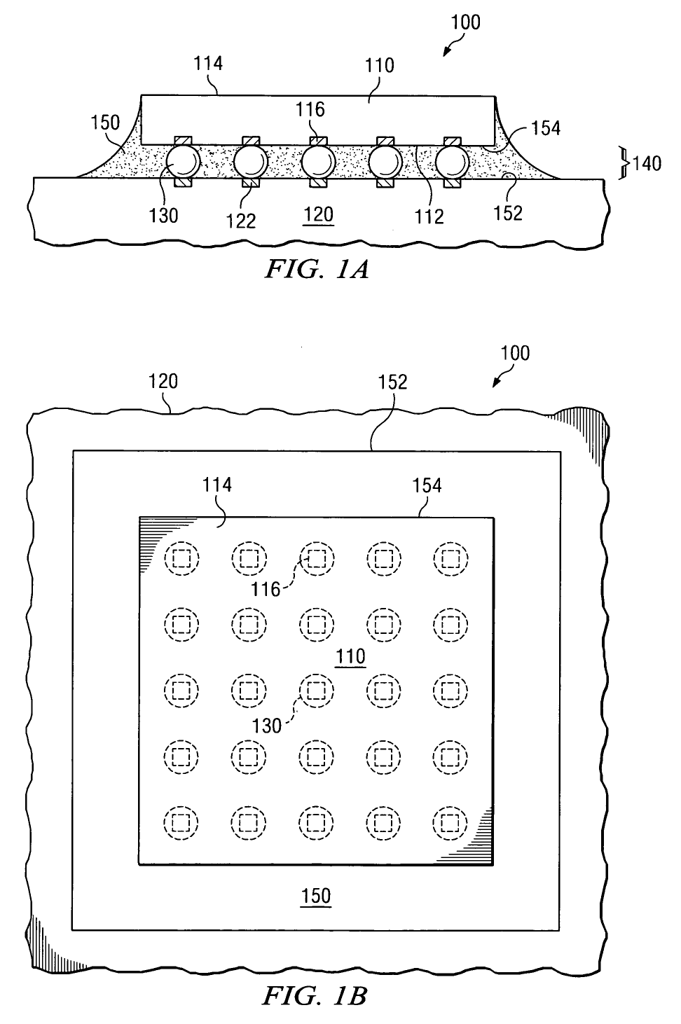

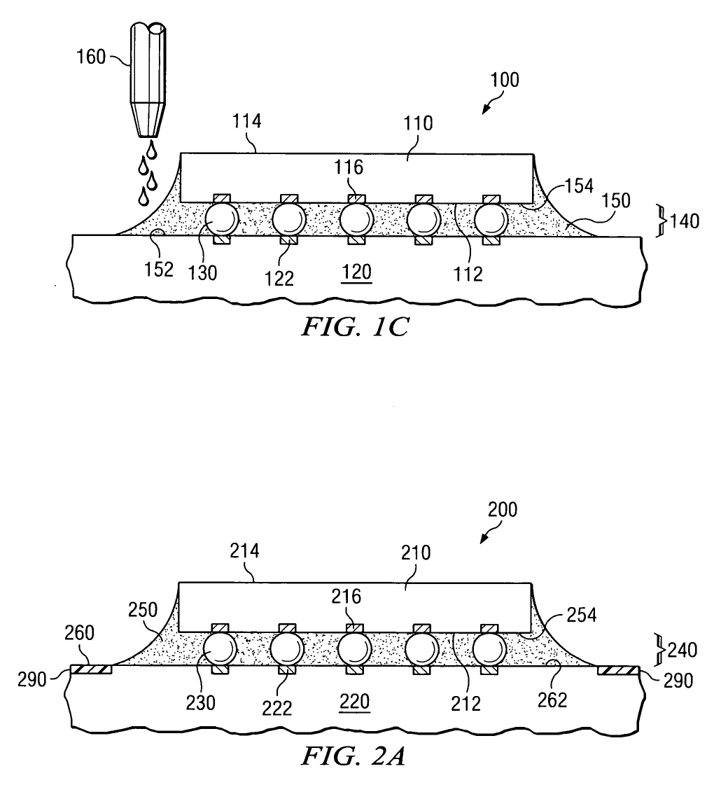

The present disclosure provides the tools and methods for dispensing underfill material uniformly and substantially without backflow and bleed in a flip chip assembly. The uniform distribution of the underfill advantageously minimizes the thermomechanical stress and improves reliability of an electronic assembly as described with reference to FIGS. 1A, 1B, 1C, 2A, and 2B.

FIG. 1A illustrates a simplified and schematic cross section of a semiconductor device assembly 100 having plasma treated components, according to an embodiment. FIG. 1B illustrates a top view of the semiconductor device assembly 100 described with reference to FIG. 1A. Referring to FIGS. 1A and 1B, the semiconductor device assembly 100 is a flip chip assembly which includes a die (or an integrated circuit chip) 110 attached to a substrate (or a flexible film, or a board) 120 using solder bumps (or conductive bumps) 130, with a gap 140 formed between the die 110 and the substrate 120 filled with an underfill (or a polymeric material) 150. The die 110, preferably formed of silicon, includes an active surface 112 and an inactive surface 114, which are planar and parallel to each other.

A surface area of the substrate 120, where a flow of the underfill 150 is desired, is described as a selective surface 152. The selective surface 152 is in direct contact with the underfill 150. Similarly, a surface area of the die 110, where a flow of the underfill 150 is desired, is described as a matching surface 154, which may be substantially the same as the active surface 112. The matching surface 154 is in direct contact with the underfill 150. In the depicted embodiment, the selective surface 152 is greater than the matching surface 154, the matching surface 154 being disposed above the selective surface 152. Thus, the gap 140 is formed between two surfaces that include the selective surface 152 of the substrate 120 and the matching surface 154 of the die 110.

A plurality of contact pads 116 are disposed on the active surface 112. In a particular embodiment, the plurality of contact pads 116 are preferably made of aluminum, copper-doped aluminum, or copper and a combination or refractory metal layer such as titanium or tungsten, and noble metal layer such as palladium, gold, or platinum. The underfill 150 is preferably made of a polymeric material having an adhesive property that mechanically couples the die 110 (having a low CTE) to the substrate 120 (having a high CTE), including any solder joints or other conductive structures therebetween.

The die 110 is mounted on the substrate 120 integral with interconnections and a plurality of terminal pads 122, yet spaced apart by the gap 140. The substrate 120 preferably includes a printed circuit board made of FR-4 or a glass-epoxy laminate, and the plurality of terminal pads 122 are preferably composed of solder-wettable copper. The die 110 is attached by reflowable solder bumps 130, which extend across the gap 140 and connect the plurality of contact pads 116 on the die 110 to a corresponding one of the plurality of terminal pads 122 on the substrate 120 both electrically and mechanically. Preferably, tin or a tin alloy (such as tin/indium, tin/bismuth, tin/lead) of a desirable melting temperature is chosen for the solder bumps 130 to accomplish the reflow at a practical temperature. Solder bumps 130 may often be referred to as “solder balls” or simply as “bumps”. For silicon packages, a protective “soldermask” (not shown) may be made of a variety of insulating materials including polymers such as polyimide. Although the die 110 is shown to be mounted as a flip chip, other types of mounting such as upright with wire bonding are also contemplated. In a particular embodiment, the semiconductor device assembly 100 may be packaged as at least one of a chip scale package (CSP) and a ball grid array (BGA) package.

Plasma is a well-known and useful tool/technology used in various applications such as in the fabrication and packaging of semiconductor devices. Typical applications may include activation and cleaning of surfaces prior to wire bonding or die attachment, resin-flow-out removal, and wafer cleaning. Additionally, surface modification and/or surface roughening of materials by plasma treatment is well-known for enhancing adhesion in underfill processes. In simplistic terms, a plasma source may be generated by applying electrical power across a pair of electrodes to a gas, the gas and the electrodes being enclosed in a plasma chamber. An object that is to receive plasma treatment is placed in the chamber, near one of the electrodes. The gas selected and the amount of electrical power provided may determine the effects of the plasma treatment on the object.

In a particular embodiment, the selective surface 152 of the substrate 120 is plasma treated (not shown), preferably prior to the reflow and underfilling processes, to advantageously improve the wetting of the underfill on the selective surface 152 compared to a non-treated surface (e.g., surface that has not received the plasma treatment). In an embodiment, the matching surface 154 of the die 110 may be plasma treated (not shown) as an option, preferably prior to the reflow and underfilling processes, to advantageously improve the wetting of the underfill on the matching surface 154 compared to the non-treated surface.

In a particular embodiment, the plasma treatment may be provided to selective areas or surfaces such as the selective surface 152 and the matching surface 154 by masking off areas or surfaces of the substrate 120 and the die 110, where a flow of the underfill 150 is not desired. The masked off areas are thereby substantially protected from the plasma treatment. The object that is to receive the plasma treatment, e.g., the substrate 120 and the die 110 with the masked off areas, is placed in the plasma chamber. After receiving the plasma treatment, the object is removed from the plasma chamber and the mask and/or the protective covering is also removed. The use of the mask thereby enables providing plasma treatment to selective areas or surfaces of the substrate 120 and the die 110.

The objective of providing the plasma treatment to selective areas of the die 110 and/or the substrate 120 is to substantially enhance the flow of the underfill 150 within a desired fillet geometry zone (e.g., the gap 140) while substantially restricting the outward flow of the underfill 150 from the desired fillet geometry zone, which includes the selective surface 152. Thus, by restricting the outward flow, the undesirable backflow and bleed of the underfill 150 is substantially minimized. Since only the selective surface 152 and the matched surface 154 have been treated with plasma, the underfill 150 preferentially wets and flows easier within the plasma treated area, thus forming the controlled fillet geometry. The plasma treatment of the selective surface 152 and the matching surface 154 also cleans and activates both of these surfaces, thereby further improving the wetting and the flow. The plasma treatment results in increasing surface energy and/or decreases contact angle of the selective surface 152 and the matching surface 154 compared to the non-treated surface. The increasing surface energy and/or decreasing contact angle reduce the possibility of the backflow and bleed of the underfill 150.

FIG. 1C illustrates a schematic cross section of a semiconductor device assembly 100 described with reference to FIG. 1A to indicate dispensing of an underfill for filling a gap, according to an embodiment. In the depicted embodiment, a nozzle 160 of an underfill dispensing device (not shown) is used for dispensing the underfill 150 onto the substrate 120 adjacent to the perimeter of the die 110. The underfill 150 is pulled into the gap 140 by capillary forces. Specifically, the nozzle 160 is positioned to dispense the underfill 150 between the selective surface 152 and the matching surface 154. Since the geometry of the gap 140 is known, an amount and/or a volume of the underfill 150 is selected to substantially match a volume of the gap 140.

In a particular embodiment, after the plasma treatment of the surfaces that form the desired fillet geometry zone (e.g., the gap 140), the underfill 150 is dispensed between the selective surface 152 and the matching surface 154 from one or more sides of the die 110 to uniformly fill the gap 140 without a substantial bleed and/or backflow of the underfill 150. Matching the volume of the gap 140 and of the dispensed underfill 150 substantially reduces the formation of voids. That is, the dispensing of the underfill 150 having a matching volume as the gap 140 is substantially contained within the gap 140, and hence within the selective surface 152 that is plasma treated. Due to surface tension, a small portion of the underfill 150 extends from an edge of the inactive surface 114 to an edge of the selective surface 152 to form a meniscus, thereby covering a side of the die 110 and the gap 140. Upon dispensing of the predefined volume, the underfill 150 (or the precursor) is heated, polymerized and “cured” to form the encapsulant.

FIG. 2A illustrates a simplified and schematic cross section of a semiconductor device assembly 200 having a flow inhibitor layer 290 applied to a selective surface of a substrate 220, according to an embodiment. FIG. 2B illustrates a top view of the semiconductor device assembly 200 described with reference to FIG. 2A. In the depicted embodiment, the semiconductor device assembly 200 is substantially the same as the semiconductor device 100 described with reference to FIGS. 1A, 1B, and 1C, except for an exclusion of the plasma treatment of the selective surface 152 and the matching surface 154, and an inclusion of the flow inhibitor layer 290. In the depicted embodiment, a flow inhibitor layer 290 is applied to cover a surface area 260 of the substrate 220 except for a selective portion 262 of the surface area 260 to substantially restrict the bleed and/or backflow of the underfill 250. In a particular embodiment, the flow inhibitor layer 290 may be fabricated from a polymer material such as polytetrafluoroethylene (PTFE) or similar other, which decreases surface energy and/or increases contact angle.

The surface area 260 of the substrate 220 that is selected for the application of the flow inhibitor layer 290 is complementary to the selective surface 152 of the substrate 120. That is, surface area that was excluded from being plasma treated as described with reference to FIGS. 1A, 1B, and 1C, is selected for the application of the flow inhibitor layer 290. The selective portion 262 of the substrate 220 that is substantially void of the flow inhibitor layer 290 is substantially the same as the selective surface 152 of the substrate 120.

As described earlier with reference to FIGS. 1A, 1B, and 1C, the objective of providing the plasma treatment to selective areas of the die 110 and/or the substrate 120 is to substantially enhance the flow of the underfill 150 within the desired fillet geometry zone (e.g., the gap 140) while substantially restricting the outward flow of the underfill 150 from the selective surface 152. Similarly, the objective of applying the flow inhibitor layer 290 to cover the surface area 260 of the substrate 220 except for the selective portion 262 is to substantially restrict the flow of the underfill 250 outside the desired fillet geometry zone (e.g., the gap 240) while enabling the flow of the underfill 150 inside the gap 240.

In an embodiment, the dispensing of the underfill 250 to fill the gap 240 is substantially the same as underfilling of the semiconductor device 100 described with reference to FIG. 1C. In a particular embodiment, after the application of the flow inhibitor layer 290 on the surfaces that are complementary to the desired fillet geometry zone (e.g., the gap 240), the underfill 250 is dispensed between the selective portion 262 and the perimeter of the die 210 from one or more sides to uniformly fill the gap 240 without a substantial bleed and/or backflow of the underfill 250. That is, the dispensing of the underfill 250 having a predefined matching volume is substantially contained within the gap 240, and hence within selective portion 262 of the substrate 220 that is substantially void of the flow inhibitor layer 290. The flow inhibitor layer 290 may be left in place or may be removed depending on packaging options, such as presence of a lid.

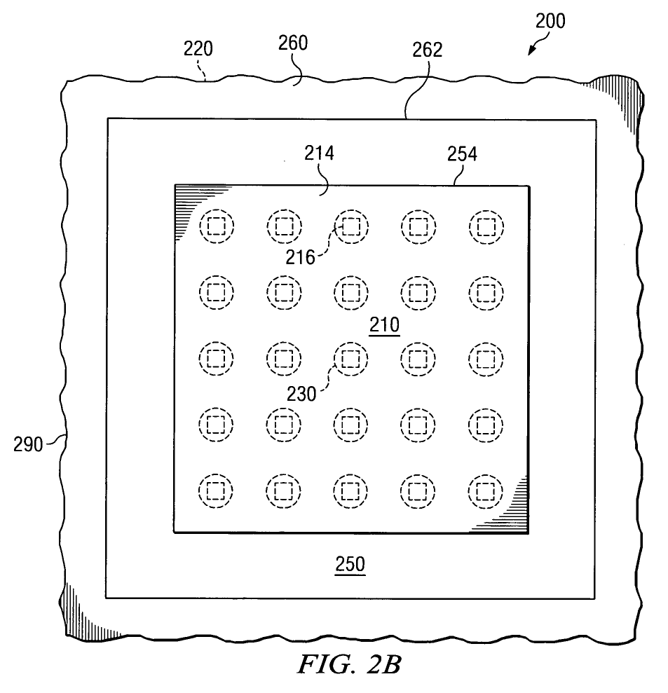

FIG. 3A is a flow chart illustrating a method for underfilling a gap disposed between a substrate and a die included in a semiconductor device assembly using a mask, according to an embodiment. In a particular embodiment, the semiconductor device assembly is substantially the same as the semiconductor device assembly 100 described with reference to FIGS. 1A, 1B, and 1C. At step 310, a selective surface of the substrate is treated by a plasma source. At step 320, an underfill is dispensed to substantially fill the gap disposed between the selective surface and a matching surface of the die. The selective surface is selectable where a flow of the underfill is desirable. The underfill is substantially contained within the gap in response to the treating.

Various steps described above may be added, omitted, combined, altered, or performed in different orders. For example, the step 310 may include a plurality of sub-steps. Additional detail of the plurality of sub-steps included in the step 310 is described with reference to FIG. 3B.

FIG. 3B is a flow chart illustrating a method for plasma treating the selective surface described with reference to FIG. 3A, according to an embodiment. At step 3102, an area of the substrate where the underfill is not desired is covered by a mask. The masked area excludes the selective surface. At 3104, the substrate is placed within a plasma chamber for exposure to the plasma source. At step 3106, the substrate is removed from the plasma chamber. At step 3108, the mask covering the area of the substrate except for the selective surface is removed. Various steps described above may be added, omitted, combined, altered, or performed in different orders.

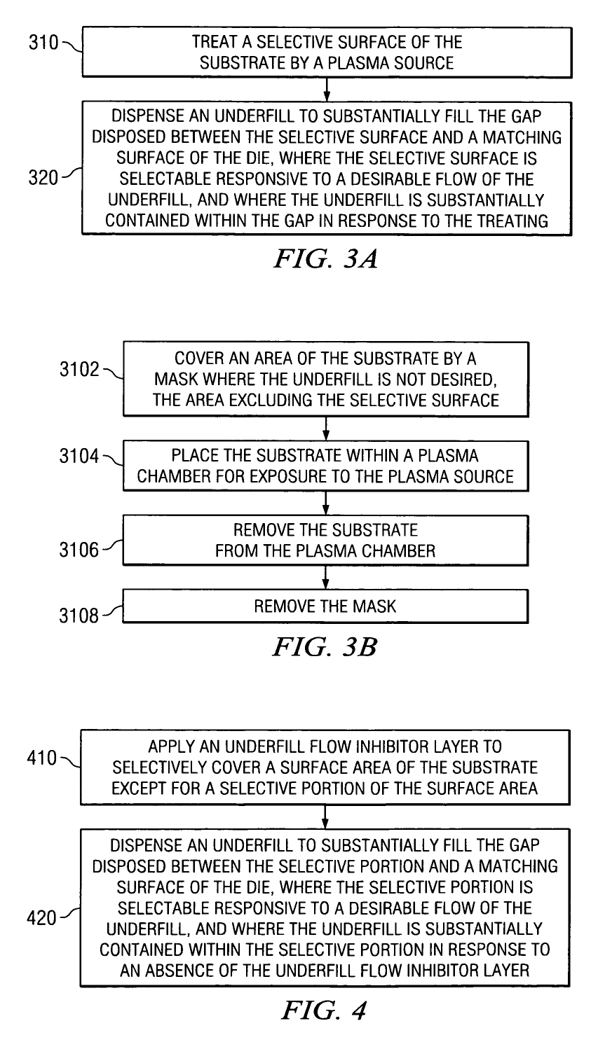

FIG. 4 is a flow chart illustrating a method for underfilling a gap disposed between a substrate and a die included in a semiconductor device assembly using a flow inhibitor, according to an embodiment. In a particular embodiment, the semiconductor device assembly is substantially the same as the semiconductor device assembly 200 described with reference to FIGS. 2A and 2B. At step 410, a surface area of the substrate is covered by an underfill flow inhibitor layer except for a selective portion. At step 420, an underfill is dispensed to substantially fill the gap disposed between the selective portion and a matching surface of the die. The selective portion is selectable where a flow of the underfill is desirable, the underfill being substantially contained within the selective portion in response to an absence of the underfill flow inhibitor layer.

Various steps described above may be added, omitted, combined, altered, or performed in different orders. For example, the step 410 may include one or more sub-steps such as applying a mask to protect the selective portion of the surface area from being covered by the underfill flow inhibitor layer.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of flip chip mounting, those of ordinary skill in the art will appreciate that the processes disclosed are capable of being used for assembly of semiconductor devices using different types of mounting techniques including conventional mounts with wire bonding.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for underfilling a gap disposed between a substrate and a die, the method comprising:
treating a selective surface of the substrate by a plasma source; and
dispensing an underfill to substantially fill the gap disposed between the selective surface and a matching surface of the die, wherein the selective surface is selectable responsive to a desirable flow of the underfill, wherein the underfill is substantially contained within the gap in response to the treating.

2. The method of claim 1 further comprising:
treating the matching surface by the plasma source, the treating of the matching surface occurring prior to the dispensing.

3. The method of claim 2, wherein the treating results in a roughening of the selective surface and the matching surface, wherein the roughening improves the flow by wetting of the underfill on the selective surface and the matching surface compared to a non-treated surface.

4. The method of claim 3, wherein the underfill is substantially contained within the gap by the wetting, wherein the wetting substantially restricts the underfill from flowing outward of the selective surface.

5. The method of claim 2, wherein the treating further results in cleaning and activating both the selective surface and the matching surface, wherein the cleaning and the activating further improves the flow by the wetting.

6. The method of claim 2, wherein the treating results in increasing surface energy of the selective surface and the matching surface compared to a non-treated surface, wherein the increasing surface energy reduces backflow and bleed of the underfill.

7. The method of claim 1, wherein a volume of the underfill that is dispensed is substantially equal to a volume enclosed by the gap.

8. The method of claim 1, wherein the selective surface is greater than the matching surface, the matching surface being disposed above the selective surface, wherein a nozzle for the dispensing of the underfill is disposed between the selective surface and the matching surface.

9. The method of claim 1, wherein the die is mounted as a flip chip, wherein the flip chip mounting is packaged as at least one of a chip scale package (CSP) and a ball grid array (BGA) package.

10. The method of claim 1, wherein the treating includes:
covering an area of the substrate by a mask where the underfill is not desired, the area excluding the selective surface;
placing the substrate within a plasma chamber for exposure to the plasma source;
removing the substrate from the plasma chamber; and
removing the mask.

11. A method for underfilling a gap disposed between a substrate and a die, the method comprising:
applying an underfill flow inhibitor layer to selectively cover a surface area of the substrate except for a selective portion of the surface area; and
dispensing an underfill to substantially fill the gap disposed between the selective portion and a matching surface of the die, wherein the selective portion is selectable responsive to a desirable flow of the underfill, wherein the underfill is substantially contained within the selective portion in response to an absence of the underfill flow inhibitor layer.

12. The method of claim 11, wherein the underfill flow inhibitor layer provides at least one of a decrease in surface energy and an increase in contact angle.

13. The method of claim 11, wherein the decrease in the surface energy and the increase in the contact angle reduces flow out and bleed of the underfill.

14. The method of claim 11, wherein the underfill flow inhibitor layer is fabricated from a polytetrafluoroethylene (PTFE) polymer.

15. The method of claim 11, wherein the applying of the underfill flow inhibitor layer occurs prior to the dispensing.

16. The method of claim 11, wherein the applying of the underfill flow inhibitor layer to the surface area reduces wetting of the underfill on the surface area compared to the selective portion, thereby substantially restricting the underfill from flowing outward of the selective portion.

17. The method of claim 11, wherein a volume of the underfill that is dispensed is substantially equal to a volume enclosed by the gap.

18. The method of claim 11, wherein the selective portion is greater than the matching surface, the matching surface being disposed above the selective portion, wherein a nozzle for the dispensing of the underfill is disposed between the selective portion and the matching surface.

19. The method of claim 11, wherein the die is mounted as a flip chip, wherein the flip chip mounting is packaged as at least one of a chip scale package (CSP) and a ball grid array (BGA) package.

20. A semiconductor device assembly comprising:
a substrate having a selective surface, the selective surface being treated by a plasma source;
a die mounted on the substrate by a plurality of coupling members, wherein the die has an active surface and a passive surface, wherein the active surface is disposed above the selective surface; and
an underfill to substantially fill a gap disposed between the selective surface and the active surface, wherein the selective surface is selectable responsive to a desirable flow of the underfill, wherein the underfill is substantially contained within the gap in response to the selective surface being treated by a plasma source.
